(19) United States
(12) Patent Application Publication
(10) Pub. No.: US 2025/0080005 A1
(43) Pub. Date: Mar. 6, 2025

(54) RECTIFYING-ELEMENT-MODULE SEALING UNIT

(71) Applicant: SANSHA ELECTRIC MANUFACTURING CO., LTD., Osaka (JP)

(72) Inventor: Kazuki TODA, Osaka (JP)

(73) Assignee: SANSHA ELECTRIC MANUFACTURING CO., LTD., Osaka (JP)

(21) Appl. No.: 18/823,889

(22) Filed: Sep. 4, 2024

(30) Foreign Application Priority Data
Sep. 4, 2023 (JP) 2023-143238

(51) Int. Cl. H02M 7/00; H02M 1/32; H02M 7/06; H05K 7/20

(52) U.S. Cl. CPC H02M 7/003; H02M 1/327; H02M 7/068; H05K 7/209

(57) ABSTRACT

A rectifying-element-module sealing unit capable of suppressing adverse effects on a rectifying element module configuring a rectifier circuit is provided. The rectifying-element-module sealing unit includes a rectifying element module having a rectifying element, a first substrate in a plate shape having a first front surface and a first back surface and having the rectifying element module arranged on the first front surface, a second substrate in a plate shape having a second front surface and a second back surface and arranged with respect to the first substrate so that the second front surface is opposed to the first front surface, and a side wall portion forming, together with the first substrate and the second substrate, a sealed space having the rectifying element module arranged therein by covering areas open sideways between the first substrate and the second substrate.

### FIELD OF THE INVENTION

The present invention relates to a rectifying-element-module sealing unit.

### DESCRIPTION OF THE BACKGROUND ART

A power conversion device includes a primary-side circuit for receiving input voltage, a secondary-side circuit for outputting output voltage, and a transformer magnetically connecting the primary-side circuit and the secondary-side circuit. The secondary-side circuit is provided with a rectifier circuit for rectifying a voltage waveform occurring at a secondary-side winding of the transformer. International Publication No. 2018/105465 discloses a power conversion device in which a switching element as a primary-side circuit, a rectifier circuit as a secondary-side circuit, an input capacitor on a primary side, an output capacitor on a secondary side, and various control circuits are arranged on a front surface of a substrate with a multilayer structure. Also, a pattern coil is formed on the substrate by a copper foil pattern or the like. With this pattern coil and a magnetic core, a transformer and so forth are formed. On a back surface of this substrate, a cooler for cooling heat of the rectifier circuit and so forth is arranged.

A heat-dissipative pattern is formed on such a substrate as described above, and heat transferred between various elements and the pattern coil in a plane direction are dissipated to the cooler via the heat-dissipative pattern. Thus, heat interference between various elements on the substrate is suppressed, these various elements can be arranged adjacently to one another, and the area of the substrate can be reduced.

### SUMMARY OF THE INVENTION

However, in the structure of International Publication No. 2018/105465, since the substrate is exposed in a state in which the rectifier circuit and others are arranged, depending on the contamination state of the exposed space due to dust, moisture, a chemical atmosphere, or the like, adherence of dust to components such as the rectifier circuit, wires and so forth on the substrate, corrosion of the components, and so forth may occur. Thus, adverse effects, such as malfunction, failure, and short life, may occur in the rectifier circuit. Therefore, it is desired to suppress adverse effects on a rectifying element module configuring a rectifier circuit.

Thus, a main object of the present invention is to provide a rectifying-element-module sealing unit capable of suppressing adverse effects on a rectifying element module configuring the rectifier circuit.

A rectifying-element-module sealing unit according to the present invention includes a rectifying element module having a rectifying element, a first substrate in a plate shape having a first front surface and a first back surface and having the rectifying element module arranged on the first front surface, a second substrate in a plate shape having a second front surface and a second back surface and arranged with respect to the first substrate so that the second front surface is opposed to the first front surface; and a side wall portion forming, together with the first substrate and the second substrate, a sealed space having the rectifying element module arranged therein by covering areas open sideways between the first substrate and the second substrate.

According to the above-described structure, it is possible to provide a rectifying-element-module sealing unit capable of suppressing adverse effects on a rectifying element module configuring a rectifier circuit.

According to the present invention, it is possible to provide a rectifying-element-module sealing unit capable of suppressing adverse effects on a rectifying element module configuring a rectifier circuit.

The above-described object and other objects, characteristics, and advantages of the present invention will become more apparent from description for carrying out the invention below refer to the drawings.

### BRIEF DESCRIPTION OF THE DRAWINGS

FIG. 1 is an upper view of a rectifier-circuit sealing unit according to an embodiment of the present invention;

FIG. 2 is an upper view of FIG. 1 when an upper second substrate is removed;

FIG. 3 is a sectional view along a III-III line in FIG. 1;

FIG. 4 is a circuit diagram of a power conversion device having a synchronous rectifier circuit;

FIG. 5A is an upper perspective view of a rectifying element module;

FIG. 5B is a back perspective view of FIG. 5A;

FIG. 6 is a current path diagram depicting a current flow in the rectifying-element-module sealing unit in FIG. 1;

FIG. 7 is an upper view of a rectifier-circuit sealing unit according to another embodiment of the present invention when an upper second substrate is removed; and

FIG. 8 is a sectional view of the rectifier-circuit sealing unit according to the other embodiment of the present invention along a III-III line of FIG. 1.

### DETAILED DESCRIPTION OF THE INVENTION

### 1. Embodiment

### (1) Structure of Rectifying-Element-Module Sealing Unit

The structure of a rectifying-element-module sealing unit 100 according to an embodiment of the present invention is described below refer to the drawings.

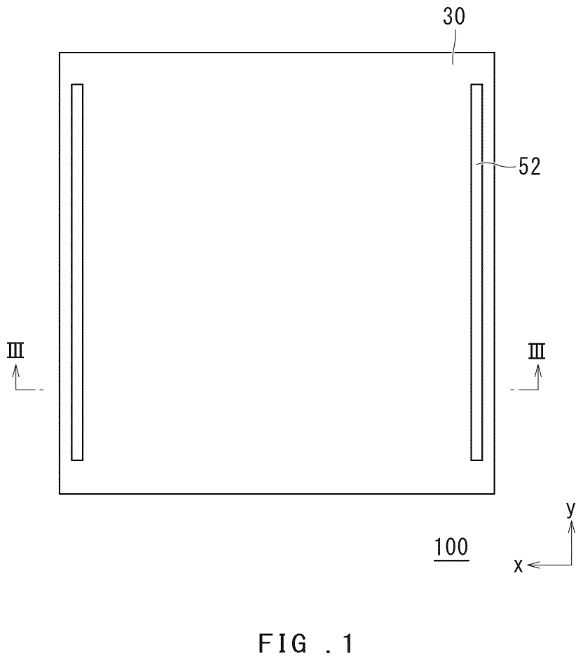

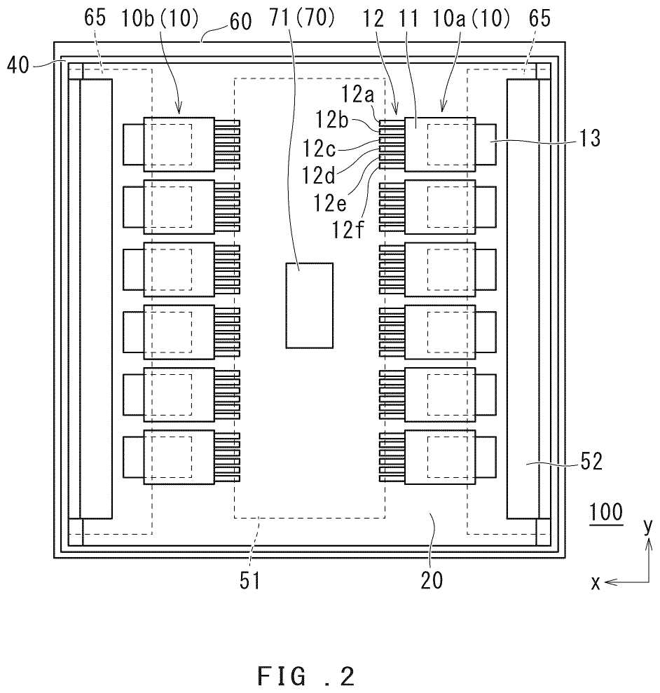

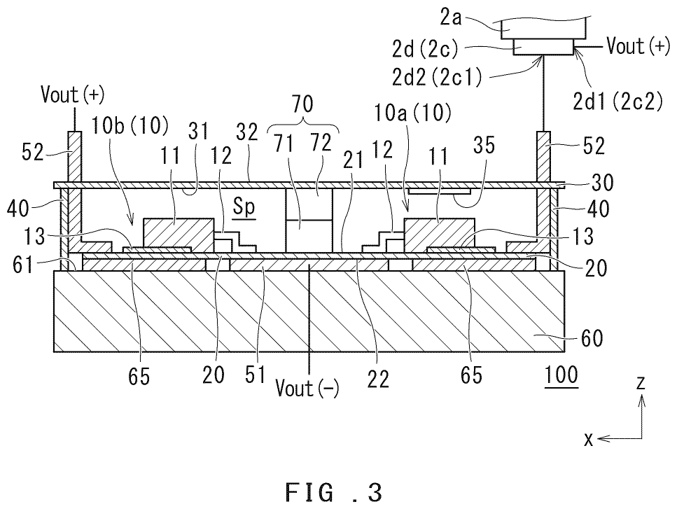

FIG. 1 is an upper view of the rectifier-circuit sealing unit according to the embodiment of the present invention. FIG. 2 is an upper view of FIG. 1 when an upper second substrate is removed. FIG. 3 is a sectional view along a III-III line in FIG. 1.

The rectifying-element-module sealing unit 100 includes at least one rectifying element module 10, a first substrate 20, a second substrate 30, and a side wall portion 40. Each rectifying element module 10 has a switching function, and has rectifying elements that each generate rectified output voltage. In the present embodiment, the plurality of rectifying element modules 10 are divided into two groups, first and second groups, that are opposed to each other in an x direction across a first wiring board 51, which will be described further below. The first group includes a plurality of rectifying element modules 10a, and the second group includes a plurality of rectifying element modules 10b. The first substrate 20 has a plate shape, and has a first front surface 21 and a first back surface 22. On the first front surface 21, the rectifying element modules 10 is arranged. The second substrate 30 has a plate shape, and has a second front surface 31 and a second back surface 32. The second substrate 30 is arranged with respect to the first substrate 20 so that the second front surface 31 is opposed to the first front surface 21. The side wall portion 40 covers areas open sideways between the first substrate 20 and the second substrate 30. With this, a space enclosed by the first substrate 20, the second substrate 30, and the side wall portion 40 forms a sealed space Sp having the rectifying element modules 10 arranged therein. The sealed space Sp is a closed space isolated from an outer space other than the space enclosed by the first substrate 20, the second substrate 30, and the side wall portion 40.

The rectifying-element-module sealing unit 100 further includes a first wiring board 51, second wiring boards 52, a cooling part 60, insulating heat dissipation sheets 65, and a connector 70. The cooling part 60 is arranged below the first substrate 20 to cool the first substrate 20. Between the first substrate 20 and the cooling part 60, the first wiring board 51 and the insulating heat dissipation sheets 65 are arranged. The first wiring board 51 electrically connects the first substrate 20 and the cooling part 60 together. The insulating heat dissipation sheets 65 electrically insulate a predetermine portion of the first substrate 20 and the cooling part 60 from each other, and also transfer heat from the first substrate 20 to the cooling part 60 for heat dissipation. The second wiring boards 52 each electrically connect at least any of elements on the second substrate 2 and an outer circuit to the rectifying element modules 10. The connector 70 electrically connects the first substrate 20 and the second substrate 30 together.

Here, in FIG. 1 to FIG. 3 and so forth, a direction in which the plurality of rectifying element modules 10a and the plurality of rectifying element modules 10b are opposed across the first wiring board 51 is set as the x direction. Also, a direction in which the plurality of rectifying element modules 10 are aligned in each of the first and second groups of the rectifying element modules 10 is set as a y direction. Note that, in FIG. 1 to FIG. 3 and so forth, the y direction is also a direction in which the first wiring board 51 extends between the plurality of rectifying element modules 10a and the plurality of rectifying element modules 10b. A direction orthogonal to the x direction and the y direction is set as a z direction, which may also be referred to a vertical direction or above/below. Furthermore, a plane parallel to an x-y plane is referred to as a horizontal plane. In the present embodiment, the first substrate 20 and the second substrate 30 goes along the horizontal plane. Each component is described below.

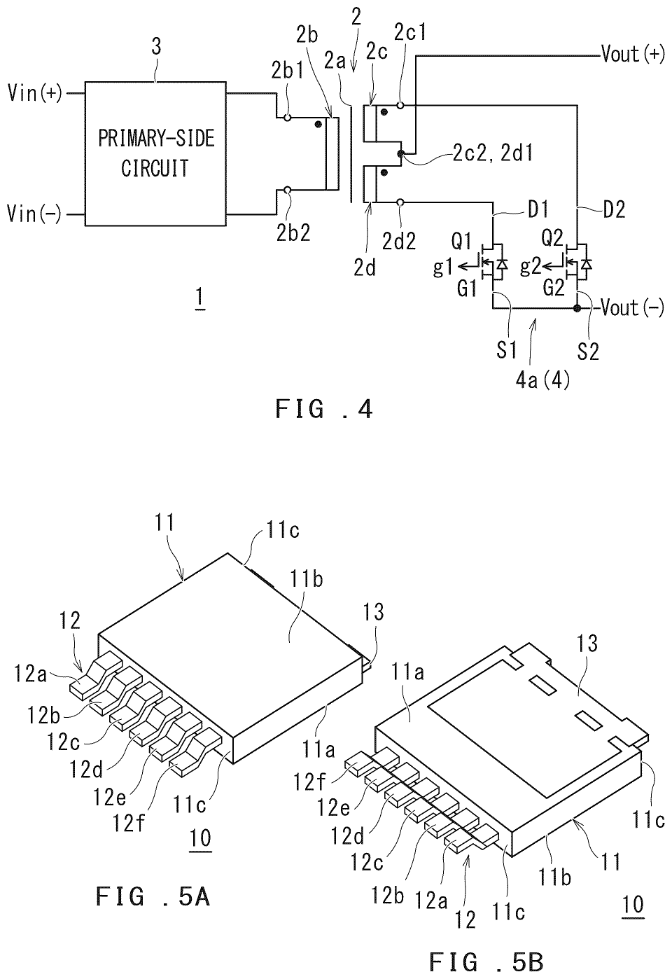

The rectifying element modules 10 each has therein a rectifying element for generating rectified output voltage. The rectifying element configures a synchronous rectifier circuit. The synchronous rectifier circuit as described above is used in a power conversion device 1. FIG. 4 is a circuit diagram of a power conversion device having a synchronous rectifier circuit.

Among a variety of power conversion devices using synchronous rectifier circuits, the power conversion device 1 described herein is of a center-tapped type, by way of example. As depicted in FIG. 4, the power conversion device 1 includes a transformer 2, a primary-side circuit 3, and a secondary-side circuit 4. The primary-side circuit 3 generates alternating voltage from direct voltage, and supplies the alternating voltage to a primary-side winding 2b of the transformer 2. Current flowing through the primary-side winding 2b generates a magnetic field, and electromagnetic induction of the magnetic field induces current to secondary-side a winding 2c-2d of the transformer 2. With this, output voltage in accordance with the turns ratio is obtained from the secondary-side winding 2c-2d.

The transformer 2 has a core 2a, the primary-side winding 2b, and the secondary-side winding 2c-2d. The primary-side winding 2b is wound from a primary-side winding start end 2b1 toward a primary-side winding finish end 2b2. The secondary-side winding 2c-2d (including a first part winding 2c and a second part winding 2d) is wound around the core 2a has. The first part winding 2c is wound around the core 2a from a first part winding start end 2cl toward a first part winding finish end 2c2. The second part winding 2d is wound around the core 2a from a second part winding start end 2d1 toward a second part winding finish end 2d2. Also, the first part winding finish end 2c2 and the second part winding start end 2d1 are connected together so that the first part winding 2c and the second part winding 2d are in series. The first part winding start end 2cl and the second part winding finish end 2d2 are connected to a secondary-side output (−) line Vout (−) via the secondary-side circuit 4. A connecting portion of the first part winding finish end 2c2 and the second part winding start end 2d1 is both connected to a secondary-side output (+) line Vout (+). From the secondary-side output (+) line Vout (+), output voltage induced in the first part winding 2c and the second part winding 2d is outputted.

The primary-side circuit 3 can be any component capable of receiving inputs of direct voltage from the primary-side input (+) line Vin (+) and the primary-side input (−) line Vin (−) to generate alternating voltage from the direct voltage. For example, the primary-side circuit 3 has a plurality of transistors or the like that receive direct voltage from the primary-side input (+) line Vin (+) and the primary-side input (−) line Vin (−). By switching the plurality of transistors, the primary-side circuit 3 can generate alternating voltage from direct voltage.

The secondary-side circuit 4 rectifies the output voltage inducted in the secondary-side winding 2c-2d. The secondary-side circuit 4 has first and second transistors Q1 and Q2 (one example of a rectifying element). The first transistor Q1 has a first gate terminal G1, a first source terminal S1, and a first drain terminal D1. The second transistor Q2 has a second gate terminal G2, a second source terminal S2, and a second drain terminal D2. To the first gate terminal G1, a first gate signal g1 is inputted. To the second gate terminal G2, a second gate signal g2 is inputted. Also, the first and second drain terminals D1 and D2 are connected to the secondary-side winding 2d-2c. Specifically, the first drain terminal D1 is connected to the second part winding finish end 2d2, and the second drain terminal D2 is connected to the first part winding start end 2cl. The first and second source terminals S1 and S2 are both connected to the secondary-side output (−) line Vout (−).

In the secondary-side circuit 4 as described above, the first and second transistors Q1 and Q2 switchably operate based on the difference in voltage applied to the first and second gate terminals G1 and G2, the first and second source terminals S1 and S2, and the first and second drain terminals D1 and D2. In the example of FIG. 4, the first and second transistors Q1 and Q2 are alternately turned ON and OFF. With this, the output voltage from the first part winding 2c and the output voltage from the second part winding 2d are alternately outputted from the secondary-side output (+) line Vout (+) and, as a result, rectified output voltage is outputted from the secondary-side output (+) line Vout (+). In the present embodiment, the first and second transistors Q1 and Q2 configure a synchronous rectifier circuit 4a.

Also, the secondary-side circuit 4 may include, in addition to the synchronous rectifier circuit 4a, a circuit related to rectification, such as a smoothing circuit.

In the present embodiment, the transistors are, for example, MOSFETs (metal oxide semiconductor field effect transistors). However, in place of MOSFETs, IGBTs (insulated gate bipolar transistors) or the like can be used.

Furthermore, in the present embodiment, the transistors are preferably power transistors, and those supporting a high current at least equal to or larger than 500 A are preferable.

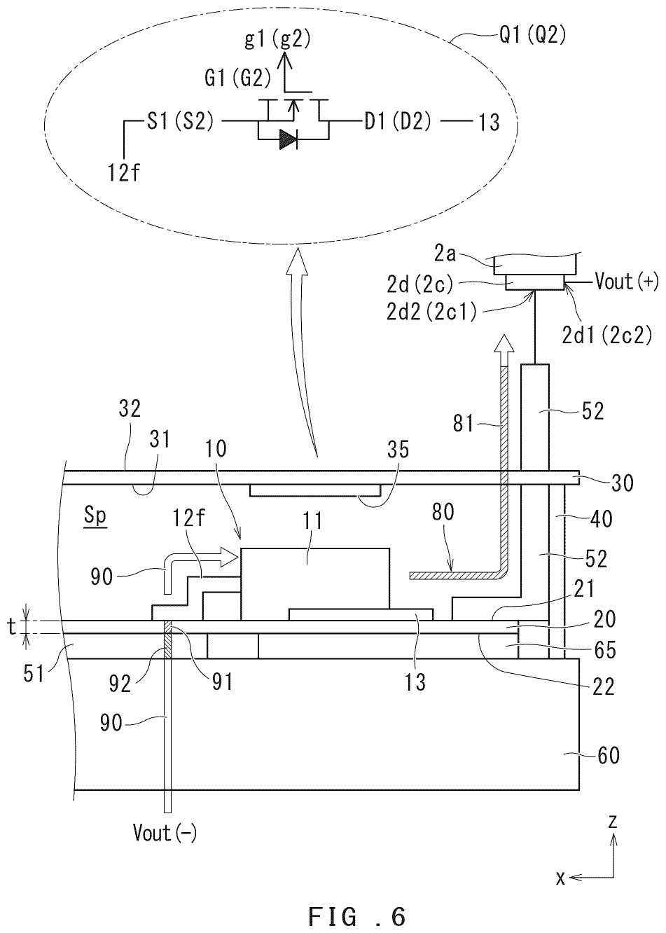

Next, the rectifying element module 10 having the first and second transistors Q1 and Q2 (one example of the rectifying elements) is described. FIG. 5A is an upper perspective view of the rectifying element module, and FIG. 5B is a back perspective view of FIG. 5A.

As depicted in FIG. 5A and FIG. 5B, the rectifying element module 10 has an element body 11, first lead terminals 12, and a second module terminal 13. Inside the element body 11, a transistor (first transistor Q1 or second transistor Q2) is arranged. With the transistor sealed with resin, the element body 11 is configured. The element body 11 has an element-body back surface 11a, an element-body front surface 11b, and element-body side surfaces 11c. In the present embodiment, the element body 11 has a substantially rectangular parallelepiped shape. The element-body back surface 11a is the back surface of the element body 11. The element-body front surface 11b is the front surface of the element body 11 opposed to the element-body back surface 11a. The element-body side surfaces 11c are side surfaces of the element body 11, which are surfaces of the element body 11 other than the element-body back surface 11a and the element-body front surface 11b.

In the following, the rectifying element module 10 is described by assuming that the first transistor Q1 is arranged inside the element body 11.

In the present embodiment, the first lead terminals 12 extend from the element body 11. The first lead terminals 12 are formed of a conductive material, for example, a metal having copper as a main component. The first lead terminals 12 include, for example, six pins 12a to 12f. The pin 12a is a gate pin, and the pin 12f is a first module terminal. The six pins 12a to 12f extend from one element-body side surface 11c toward the element-body back surface 11a and are aligned in sequence. The first module terminal 12f is electrically connected to the first source terminal S1. The gate pin 12a is electrically connected to the first gate terminal G1. The gate pin 12a and the first module terminal 12f extend from one element-body side surface 11c to the outside of the element body 11 and also extend toward the element-body back surface 11a. Although this is not meant to be restrictive, in the present embodiment, the gate pin 12a and the first module terminal 12f each have a portion extending from the element-body side surface 11c along the element-body back surface 11a and a portion bent or curved from a tip of said portion and then extending toward the element-body back surface 11a. Also, the one element-body side surface 11c from which the gate pin 12a and the first module terminal 12f extend is a surface opposed a side where part of the second module terminal 13 protrudes from the element body 11. That is, the direction in which the first lead terminals 12 extend from the element body 11 and the direction in which the second module terminal 13 protrudes from the element body 11 are opposed to each other.

The second module terminal 13 is electrically connected to the first drain terminal D1. The second module terminal 13 is arranged at least partially in contact with the element-body back surface 11a. In the present embodiment, the second module terminal 13 has a plate shape extending along the element-body back surface 11a, and is arranged partially in surface contact with the element-body back surface 11a. The second module terminal 13 is arranged so as to be flush with the element-body back surface 11a. Also, the second module terminal 13 has the remaining portion not in contact with the element-body back surface 11a extending from one element-body side surface 11c along the element-body back surface 11a to the outside of the element body 11 toward a direction opposite to a direction in which the first module terminal 12f extends from the element body 11. The second module terminal 13 as described above is formed of a conductive material, for example, a metal having copper as a main component.

In the above-described rectifying element module 10, the first module terminal 12f extends to the outside of the element body 11 and also extends toward the element-body back surface 11a, and the second module terminal 13 is arranged at least partially in contact with the element-body back surface 11a. The above-described rectifying element module 10 is, for example, a surface mount component in the above-described state as a standard state. Thus, since the rectifying element module 10 in the standard state can be attached to the first substrate 20, normal attachment is only required, and no additional work is required.

As depicted in FIG. 1 to FIG. 3, the first substrate 20 is to arrange the rectifying element module 10. The first substrate 20 is formed in a plate shape and has the first front surface 21 and the first back surface 22. The first substrate 20 is arranged along an arrangement surface 61 of the cooling part 60. Here, the first substrate 20 is arranged along the horizontal plane, and the first front surface 21 and the first back surface 22 are along the horizontal plane. The rectifying element module 10 is arranged on the first front surface 21 of the first substrate 20. In the example of FIG. 1 to FIG. 3, the first group including the plurality of rectifying element modules 10a and the second group including the plurality of rectifying element modules 10b are arranged on the first substrate 20 so as to be opposed by centering a center portion of the first substrate 20 in the x direction. On the first front surface 21, a first connector 71 is arranged between the rectifying element modules 10a and the rectifying element modules 10b.

In each rectifying element module 10, the first module terminal 12f extends from the element-body side surface 11c of the element body 11 along the element-body back surface 11a, and the tip extending toward the element-body back surface 11a is attached to the first substrate 20. In the present embodiment, the first module terminal 12f extends from the element-body side surface 11c in the x direction and downward in the z direction, and is attached to the first substrate 20. Furthermore, the first module terminal 12f is electrically connected to the first wiring board 51 via a penetrating member, which is not depicted. The penetrating member is formed of a conductive member penetrating through the first substrate 20 in a thickness direction (z direction) from the first front surface 21 to the first back surface 22. Also, as with the first module terminal 12f, the gate pin 12a extends along the element-body back surface 11a and the tip extending toward the element-body back surface 11a is attached to the first substrate 20. For example, the gate pin 12a is electrically connected to a gate signal circuit, which is not depicted, via a wire (not depicted) on the first substrate 20, to receive a supply of a first gate signal g1.

The element body 11 and the second module terminal 13 are in contact with each other in a state of being along the first front surface 21. The second module terminal 13 is electrically connected to the second wiring board 52.

On the first front surface 21 of the first substrate 20, the rectifying element modules 10 are arranged as first-substrate components. The first-substrate components are not limited to the rectifying element modules 10 and can be various electronic components other than the rectifying element modules 10, wires other than wires for the rectifying element modules 10, and others. An example of the first-substrate components other than the rectifying element modules 10 can be an electronic component not adversely affected by malfunction, destruction, or the like due to heat generation from the rectifying element modules 10. Other examples of the first-substrate components other than the rectifying element modules 10 can be: a chip ceramic capacitor for smoothing power supply and taking measures on noise, or the like; a chip resistor for a gate resistor or the like; and various connectors for wired connection or the like for input and output of a gate signal, power supply, or the like.

The second substrate 30 is arranged so as to be opposed to the first substrate 20 in a state in which the second front surface 31 of the second substrate 30 and the first front surface 21 of the first substrate 20 are opposed to each other. The second substrate 30 is formed in a plate shape and has the second front surface 31 and the second back surface 32. The second substrate 30 is arranged along the first substrate 20. Here, the second substrate 30 is arranged along the horizontal plane, and the second front surface 31 and the second back surface 32 are along the horizontal plane. On the second front surface 31 of the second substrate 30, a second-substrate component 35 is arranged. The second-substrate component 35 can configure a secondary-side circuit 4 together with, for example, the rectifying element modules 10 of the first substrate. The first substrate 20 and the second substrate 30 are electrically connected to each other via, for example, the connector 70 or the like, and the first-substrate components including the rectifying element modules 10 and the second-substrate component 35 are electrically connected to each other. Also, on the second front surface 31, a second connector 72 is arranged so as to correspond to the first connector 71. With the first connector 71 and the second connector 72 coupled to each other, the connector 70 is formed, so that the first substrate 20 and the second substrate 30 are electrically connected to each other.

Note that, on the second front surface 31 of the second substrate 30, for example, the second-substrate component 35, a wire, and so forth are preferably arranged because they have a possibility of being adversely affected by malfunction, destruction, or the like due to heat generation from the rectifying element modules 10. Examples of the second-substrate component 35 arranged on the second front surface 31 can be: a chip ceramic capacitor for smoothing power supply, and taking measures on noise, or the like; an electrolytic capacitor such as a circuit for smoothing power supply or for reverse bias; various connectors for wired connection or the like for input and output of a gate signal, an abnormal signal, power supply, or the like; a fast recovery diode (FRD) as a protective circuit; a Zener diode as a protective circuit or a constant voltage source; a photocoupler for gate signal transmission; a driving circuit for gate signal transmission; and a chip resistor for a gate resistor.

As the first substrate 20, a resin substrate made of relatively-inexpensive glass epoxy resin, a ceramic substrate, or the like can be used. Also, the first substrate 20 for use can be relatively thin, such as having a thickness, for example, equal to or larger than 1.6 mm and equal to or smaller than 2.0 mm. As the second substrate 30, a resin substrate made of relatively-inexpensive glass epoxy resin or the like can be used. Also, the second substrate 30 for use can be relatively thin, such as having a thickness, for example, equal to or larger than 1.6 mm and equal to or smaller than 2.0 mm.

The side wall portion 40 covers areas open sideways between the first substrate 20 and the second substrate 30 horizontally arranged and opposed to each other. The side wall portion 40 is in a plate shape and is arranged vertically with respect to the first substrate 20 and the second substrate 30. The side wall portion 40 is formed of, for example, an insulating member. In the example of FIG. 3, the side wall portion 40 extends from the cooling part 60 in the z direction at positions corresponding to both edge portions of the first and second substrates 20 and 30. A space enclosed by the first substrate 20, the second substrate 30, and the side wall portion 40 forms the sealed space Sp. In the sealed space Sp, the first front surface 21 of the first substrate 20, the second front surface 31 of the second substrate 30, the rectifying element modules 10, and part of the second wiring boards 52 are positioned.

Note that, in FIG. 3, it is also possible to include the arrangement surface 61 of the cooling part 60 to the second front surface 31 of the second substrate 30 in the sealed space Sp. Thus, the first substrate 20, the second front surface 31 of the second substrate 30, the arrangement surface 61 of the cooling part 60, the rectifying element modules 10, the first wiring board 51, part of the second wiring boards 52, and the insulating heat dissipation sheets 65 may be positioned in the sealed space Sp.

The first wiring board 51 is arranged between the first substrate 20 and the cooling part 60 in contact with the first back surface 22 of the first substrate 20 and the arrangement surface 61 of the cooling part 60. In the example of FIG. 2 and FIG. 3, the first wiring board 51 has a plate shape, extends in a longitudinal direction as the y direction, and is formed of a conductive material such as Cu, Al, or the like. Across the first wiring board 51 extending in the y direction, the rectifying element modules 10a of the first group and the rectifying element modules 10b of the second group are arranged on the first substrate 20 so as to be opposed to each other. Each of the first lead terminals 12 of the plurality of rectifying element modules 10a and each of the first lead terminals 12 of the plurality of rectifying element modules 10b are opposed to each other by centering the center portion of the first substrate 20 in the x direction. In this case, the first module terminal 12f of each rectifying element module 10a of the first group is opposed to the first module terminal 12f of each rectifying element module 10b of the second group across the first wiring board 51. Also, the first module terminal 12f of the rectifying element module 10a extends toward the first wiring board 51 and is connected to the first wiring board 51 via a penetrating member penetrating through the first substrate 20. Similarly, the first module terminal 12f of the rectifying element module 10b extends toward the first wiring board 51 and is connected to the first wiring board 51 via a penetrating member penetrating through the first substrate 20. The first wiring board 51 connects, for example, the first module terminal 12f of the rectifying element module 10 via the cooling part 60 to the secondary-side output (−) line Vout (−).

The second wiring boards 52 are arranged on the first front surface 21 of the first substrate 20 and extend to the outside of the rectifying-element-module sealing unit 100. In the example of FIG. 2 and FIG. 3, the second wiring boards 52 have one second wiring board 52 corresponding to the rectifying element modules 10a of the first group and another second wiring board 52 corresponding to the rectifying element modules 10b of the second group. The second wiring boards 52 are arranged so as to be opposed to each other with respect to the center in the x direction. Each second wiring board 52 has a plate shape bent on an xz plane, and extends to the y direction. The second wiring board 52 is formed of a conductive material such as Cu or Al. In the second wiring board 52, one bent portion of is arranged on the first front surface 21 of the first substrate 20, and the other bent portion of the second wiring board 52 is arranged along the side wall portion 40. The second wiring boards 52 extends above along the side wall portion 40 to extend to the outside of the rectifying-element-module sealing unit 100. Each second wiring board 52 is electrically connected to the second module terminal 13 of the rectifying element module 10 of the first substrate 20. For example, each second wiring board 52 connects the second module terminal 13 of the rectifying element module 10 to the secondary-side output (+) line Vout (+).

Note that the first wiring board 51 may electrically connect the first module terminal 12f and the secondary-side output (+) line Vout (+) together, and the second wiring board 52 may electrically connect the second module terminal 13 and the secondary-side output (−) line Vout (−) together.

The cooling part 60 cools at least the first substrate 20. The cooling part 60 is formed of a conductive material such as Cu or Al. In the example of FIG. 3, the cooling part 60 has the arrangement surface 61, which is an upper surface of the cooling part 60 and is also a horizontal plane. On the cooling part 60, the first wiring board 51 and the insulating heat dissipation sheets 65 are arranged on the arrangement surface 61. Also, on the cooling part 60, the first substrate 20 is arranged via the first wiring board 51 and the insulating heat dissipation sheets 65. The insulating heat dissipation sheets 65 are separately arranged at two locations. One insulating heat dissipation sheet 65 is arranged on the cooling part 60 so as to correspond to a portion of the first substrate 20 where the rectifying element modules 10a of the first group are arranged. The other insulating heat dissipation sheet 65 is arranged on the cooling part 60 so as to correspond to a portion of the first substrate 20 where the rectifying element modules 10b of the second group are arranged. Thus, the rectifying element modules 10a of the first group and the rectifying element modules 10b of the second group can be insulated from one another, and also heat from the first substrate 20 and the rectifying element modules 10 can be dissipated. Note that the insulating heat dissipation sheets 65 may be arranged so as to correspond to either of the rectifying element modules 10a of the first group and the rectifying element modules 10b of the second group.

When the rectifying element module 10 has the first transistor Q1, the cooling part 60 cools mainly heat due to a first current passing through the first source terminal S1 and a second current passing through the second drain terminal D1. Since a relatively large first current and second current flows through the rectifying element module 10, heat generated by the first current and the second current is also relatively large. Heat due to the first current and the second current can be thought to be generated in the rectifying element module 10, generated in the first substrate 20 through which the first current and the second current pass, or the like. The cooling part 60 can cool heat of the first substrate 20 and the rectifying element modules 10 due to the first current and the second current as described above.

The cooling part 60 is only required to be able to cool the first substrate 20 and the rectifying element modules 10, and the structure of the cooling part 60 is not limited. Examples of the cooling part 60 include a water-cooled heat sink configured of one or more fins and conduits and so forth and capable of letting liquid such as water pass therethrough, an air-cooled heat sink configured of one or more fins and capable of dissipating heat, and so forth.

Note that while the above description has been made in relation to a case in which the first transistor Q1 is arranged inside the rectifying element module 10, a brief description is made below on a case in which the second transistor Q2 is arranged inside the rectifying element module 10, by focusing on different points.

The first module terminal 12f is electrically connected to the second source terminal S2. The gate pin 12a is electrically connected to the second gate terminal G2. The second module terminal 13 is electrically connected to the second drain terminal D2.

The first module terminal 12f extends to the outside of the element body 11, and also extends toward the element-body back surface 11a, and is attached to the first substrate 20. The first module terminal 12f is electrically connected to the cooling part 60 via a penetrating member penetrating through the first substrate 20. The gate pin 12a extends to the outside of the element body 11 and also extends toward the element-body back surface 11a, and is attached to the first substrate 20. For example, the gate pin 12a is electrically connected to the gate signal circuit, which is not depicted, via a wire (not depicted) on the first substrate 20, to receive a supply of a second gate signal g2.

Also, the second source terminal S2 and the secondary-side output (−) line Vout (−) are electrically connected to each other, and the cooling part 60 cools mainly heat due to the first current passing through the second source terminal S2. Also, the second drain terminal D2 and the first part winding start end 2cl of the first part winding 2c are electrically connected to each other, and the cooling part 60 cools mainly heat due to the second current passing through the second drain terminal D2.

### (2) Arrangement and Structure of Entire Rectifying-Element-Module Sealing Unit

Next, the arrangement and structure of the rectifying element module 10, the first substrate 20, the second substrate 30, the side wall portion 40, the first wiring board 51, the second wiring board 52, the cooling part 60, the insulating heat dissipation sheets 65, and the connector 70 in the rectifying-element-module sealing unit 100 are summarized and further described.

In the rectifying-element-module sealing unit 100 of the present embodiment, the cooling part 60 is arranged on a lowermost portion, and a pair of insulating heat dissipation sheets 65 are arranged on the arrangement surface of this cooling part 60 so as to opposed to each other across the first wiring board 51 in the x direction. The first substrate 20 is arranged on upper surfaces of the first wiring board 51 and the pair of the insulating heat dissipation sheets 65. On the first substrate 20, the rectifying element modules 10a are arranged so as to correspond to one insulating heat dissipation sheet 65, and the rectifying element modules 10b are arranged so as to correspond to the other insulating heat dissipation sheet 65. The first module terminals 12f of the rectifying element modules 10a and 10b are arranged so as to face each other in the x direction. Each first module terminal 12f is electrically connected to the first wiring board 51 via a penetrating member not depicted herein penetrating through the first substrate 20. The first wiring board 51 is electrically connected to the secondary-side output (−) line Vout (−) via the cooling part 60. Also, the pair of the second wiring boards 52 are arranged so as to be opposed to each other with respect to the center in the x direction. The second wiring boards 52 are electrically connected to the second module terminals 13 of the rectifying element modules 10a and 10b, respectively. The second substrate 30 is arranged so as to be opposed to the first substrate 20. The second wiring boards 52 along the side wall portion 40 each penetrate through an end portion of the second substrate 30 to be extended to the outside and electrically connected to the secondary-side output (+) line Vout (+).

The above-described structure forms the sealed space Sp enclosed by the first substrate 20, the second substrate 30, and the side wall portion 40. In the sealed space Sp, at least rectifying element module 10 is arranged and, in addition, the first front surface 21 of the first substrate 20, the second front surface 31 of the second substrate 30, part of the second wiring board 52, and others are arranged.

In the present embodiment, at a center portion of the first substrate 20, that is, between the rectifying element modules 10a and 10b, the connector 70 electrically connecting the first substrate 20 and the second substrate 30 together is arranged. Also, the connector 70 is arranged, for example, at a center portion of the first substrate 20 and the second substrate 30.

In the present embodiment, as depicted in FIG. 2, the plurality of rectifying element modules 10 are arranged on the first front surface 21 so as to be aligned in the y direction. The rectifying element modules 10 each have the first transistor Q1 or the second transistor Q2 as appropriate. The structure and arrangement of each rectifying element module 10 are similar to those described above.

### (3) Current Path

Next, a current flow in the rectifying-element-module sealing unit 100 is described. The current flow in the rectifying-element-module sealing unit 100 is the same in both of a case in which the first transistor Q1 is arranged inside the rectifying element module 10 and a case in which the second transistor Q2 is arranged therein.

FIG. 6 is a current path diagram depicting a current flow in the rectifying-element-module sealing unit in FIG. 1.

Part of the first current path 90 of the first current from the first source terminal S1 (or second source terminal S2) via the first module terminal 12f to the secondary-side output (−) line Vout (−) is configured of a first penetrating current path 91 for the first current penetrating through the first substrate 20 from the first front surface 21 to the first back surface 22. The length of the first penetrating current path 91 is equivalent to a thickness t of the first substrate 20 from the first front surface 21 to the first back surface 22. Also, in part of the first current path 90, a first wiring board current path 92 through which the first current passes the first wiring board 51 is further included.

In part of a second current path 80 of the second current from the first drain terminal D1 (or second drain terminal D2) via the second module terminal 13 and the second part winding 2d (or first part winding 2c) to the secondary-side output (+) line Vout (+), a second wiring board current path 81 is included through which the second current passes the second wiring board 52.

When the first transistor Q1 is turned ON and the second transistor Q2 is turned OFF, a signal from the secondary-side output (−) line Vout (−) is transmitted to the first source terminal S1as a first current via the first current path 90 including the first penetrating current path 91 and the first wiring board current path 92 and a current flows from the first source terminal S1 to the first drain terminal D1. Next, a second current flows from the first drain terminal D1 to the second part winding finish end 2d2 of the second part winding 2d via the second current path 80 including the second wiring board current path 81. Then, output voltage induced at the second part winding 2d is outputted from the second part winding start end 2d1 and the secondary-side output (+) line Vout (+).

On the other hand, when the second transistor Q2 is turned ON and the first transistor Q1 is turned OFF, a signal from the secondary-side output (−) line Vout (−) is transmitted to the second source terminal S2 as a first current via the first current path 90 including the first penetrating current path 91 and the first wiring board current path 92, and a current flows from the second source terminal S2 to the second drain terminal D2. Next, a second current flows from the second drain terminal D2 to the first part winding start end 2cl of the first part winding 2c via the second current path 80 including the second wiring board current path 81. Then, output voltage induced at the first part winding 2c is outputted from the first part winding finish end 2c2 and the secondary-side output (+) line Vout (+).

### (4) Operation and Effect

(4-1)

According to the above-described structure, since the rectifying element modules 10 are arranged in the sealed space Sp, it is possible to isolate the rectifying element modules 10 from the external environment in a contaminated state due to dust, moisture, a chemical atmosphere, or the like. Description is made further below.

Here, a rectifier circuit for generating rectified output voltage is configured by, for example, combining the plurality of rectifying element modules 10 as described above. Each rectifying element module 10 can have the first and second transistors Q1 and Q2 (one example of the rectifying element) having a switching function and the module terminals 12f and 13 for input/output of a signal to the first and second transistors Q1 and Q2 (one example of the rectifying element). The first and second transistors Q1 and Q2 (one example of the rectifying element) are each configured, for example, as the element body 11 molded with mold resin or the like with the first and second transistors Q1 and Q2 (one example of the rectifying element) arranged therein. The module terminals 12f and 13 are terminals electrically connected to the first and second transistors Q1 and Q2 (one example of the rectifying element), and are extended from the element body 11 to the outside. The module terminals 12f and 13 perform input/output of signals between the wires and so forth for the rectifying element modules 10 and the first and second transistors Q1 and Q2 (one example of the rectifying element).

According to the above-described structure, since these rectifying element modules 10 are arranged in the sealed space Sp, it is possible to isolate the rectifying element modules 10 from the external environment with a high degree of contamination. Thus, it is possible to suppress contamination, corrosion, adherence of dust to the rectifying element modules 10. This can also suppress adverse effects, such as malfunction, failure, and short life, on the first and second transistors Q1 and Q2 (one example of the rectifying element) in the rectifying element modules 10 and, in turn, the rectifier circuit. In particular, it is possible to isolate the module terminals 12f and 13 not covered with molding resin from the external environment with a high degree of contamination.

The rectifying element modules 10 may be used in an environment with a high degree of contamination, such as a site (factory) for metal plating. Cooling the rectifying element modules 10 is performed by drawing air in this environment with a high degree of contamination. Thus, if the rectifying element modules 10 are not arranged in the sealed space Sp, the rectifying element modules 10 are positively exposed to the environment with a high degree of contamination, thereby causing adverse effects, such as malfunction, on a rectifier circuit configured of the rectifying element modules 10. According to the above-described rectifying-element-module sealing unit 100, it is possible to isolate the rectifier circuit from the external environment with a high degree of contamination.

Also, wires and so forth for the rectifying element modules 10 can be formed on the first front surface 21 of the first substrate 20. Since the first front surface 21 is positioned in the sealed space Sp, it is possible to suppress contamination, corrosion, adherence of dust to the wires and so forth for the rectifying element modules 10. This can suppress adverse effects, such as failure of wires and so forth for the rectifying element modules 10, signal cutoff due to an open circuit or the like, and noise in a signal. Note that, with wires and so forth other than the wires for the rectifying element modules 10 arranged in the sealed space Sp, it is possible to suppress adverse effects on those wires.

Furthermore, in the above-described rectifying-element-module sealing unit 100, since the rectifier element modules 10 are formed on the first substrate 20, it is possible to reduce the size and cost of the rectifying-element-module sealing unit 100. Description is specifically made below.

As described above, since the external environment where the rectifying element modules 10 are used may have a high degree of contamination, it is required to suppress malfunction and so forth of the rectifier circuit due to contamination. Thus, to isolate a relatively-large rectifying element configured of a diode that has been currently used from the external environment, the rectifying element is sealed in a mold resin to form a relatively large molded component. Also, the molded component and another component are connected by not using a wire on the substrate but by using, for example, a copper wire or the like having a large thickness and a large width and covered with an insulating material. Thus, while not exposed to the external environment, the rectifier circuit formed of the molded component and the copper wire or the like covered with the insulating material invites an increase in size and cost. By contrast, in the above-described structure, the relatively-small rectifying element modules 10 arranged on the first substrate 20 are arranged together with the first substrate 20 in the sealed space Sp. Furthermore, connections among the rectifying element modules 10 and connections between each rectifying element module 10 and another element can be made with relatively thin wires or the like formed on the first substrate 20. Still further, the first substrate 20 itself also has a plate shape and its thickness is thin. Thus, by adopting the above-described rectifying-element-module sealing unit 100, a reduction in size and cost can be achieved.

(4-2)

According to the above-described structure, while the rectifying element modules 10 are arranged on the first substrate 20, the second-substrate component 35, wires, and so forth having performance that tends to be degraded by an influence of heat of the rectifying element modules 10 are arranged on the second substrate 30, which is different from the first substrate 20. This can isolate the components that tend to be affected by heat and so forth from the rectifying element modules 10. Thus, compared with a case in which the rectifying element modules 10 and the components that tend to be affected by heat are arranged on the same substrate, it is possible to suppress the influence of heat on the components that tend to be affected by heat.

Also, since the second front surface 31 of the second substrate 30 is also positioned inside the sealed space Sp, it is possible to suppress adverse effects, such as malfunction, failure, and short life, on the second-substrate component 35, wires, and so forth that are arranged on the second substrate 30 and tend to be affected by heat.

Furthermore, since the first substrate 20 and the second substrate 30 are opposed to each other, an electrical connection between the first substrate 20 and the second substrate 30 can be ensured with ease.

(4-3)

According to the above-described structure, the rectifying element modules 10 are included in the secondary-side circuit 4 connected to the transformer 2, where a high current flows and heat generation can easily become large. According to the above-described structure, it is possible to arrange, on the second substrate 30, the second-substrate component 35, wires, and so forth that tend to be affected by heat, thereby isolating them from the first substrate 20 where the rectifying element modules 10 are arranged. Thus, the components that tend to be affected by heat on the second substrate 30 can be protected from the influence of heat. Thus, the above-described rectifying-element-module sealing unit 100 is useful when applied to the secondary-side circuit 4 of the transformer 2.

(4-4)

According to the above-described structure, the rectifying element modules 10 are arranged on the first front surface 21 of the first substrate 20, and the cooling part 60 is provided on the first back surface 22 side of the first substrate 20. Thus, heat of the first substrate 20 where the rectifying element modules 10 are arranged can be cooled with ease by the cooling part 60.

(4-5)

According to the above-described structure, part of the first current path 90 of current flowing through the rectifying element module 10 is configured of the first penetrating current path 91. Thus, compared with a case in which the entire first current path 90 is formed as a wire on the first substrate 20, it is possible to suppress heat of the first substrate 20 generated by which the current flowing through the rectifying element module 10 flows on the first substrate 20. That is, by reducing the wire length where current flows in the first substrate 20, heat of the first substrate 20 due to current flowing through that wire can be suppressed. Thus, heat generation of the rectifying element module 10 due to the influence of heat of the first substrate 20 can be suppressed. Furthermore, heat of the first substrate 20 and the rectifying element modules 10 is cooled by the cooling part 60. These can also suppress destruction and so forth of the rectifying element modules 10 due to heat.

(4-6)

According to the above-described structure, in a state of being opposed to each other, the first substrate 20 and the second substrate 30 can be supported by the connector 70, and these substrates 20 and 30 can also be electrically connected together.

(4-7)

According to the above-described structure, the side wall portion 40 formed of an insulating member can inhibit current from flowing through the side wall portion 40, and a current path is formed with a desired path.

Note that while the embodiment of the present invention is disclosed in the description above, the present invention is not limited to the embodiment described above.

That is, it is possible to variously change any mechanism, shape, material, quantity, position, arrangement, or the like of the embodiment described above without deviating from the scope of the technical idea and object of the present invention, and those changes are included in the present invention.

### 2. Modifications

### (1) On Sealed Space Sp

In the rectifying-element-module sealing unit 100 described in the above-described embodiment, the sealed space Sp is configured by combining the first substrate 20, the second substrate 30, and the side wall portion 40. However, it is sufficient to be able to form the sealed space Sp, and the side wall portion 40 can be omitted. For example, by functioning a portion obtained by bending the edge portion of the first substrate 20 or by bending the edge portion of the second substrate 30 as the side wall portion 40, the sealed space Sp can be formed by using the first substrate 20 and the second substrate 30.

Further, in the above-described embodiment, the sidewall portion 40 is formed of an insulating material. However, the sidewall portion 40 may be formed of a material similar to that of the first substrate 20 and the second substrate 30, for example, a substrate.

### (2) On Rectifying Element Module

In the above-described embodiment, in each rectifying element module 10, the first lead terminals 12 are extended from the element-body side surface 11c, and the second module terminal 13 extends along the element-body back surface 11a. However, in the rectifying element module 10, the second module terminal 13 of the element-body back surface 11a may not be used as a terminal, and only the first lead terminals 12 may be used as terminals. For example, the first lead terminals 12 include the gate pin 12a receiving an input of a gate signal, the first module terminal 12f electrically connected to the first source terminal S1, and the second module terminal 12d electrically connected to the first drain terminal D1. The second module terminal 12d is electrically connected to the second wiring board 52. In this case, the second module terminal 12d is used in place of the second module terminal 13 in the above-described embodiment.

Also, the above-described rectifying element module 10 is a surface mount component. However, the mode of the rectifying element module 10 is not limited and may be, for example, a discrete component.

### (3) On Electronic Component on Second Substrate

In the above-described embodiment, the second-substrate component 35 is arranged on the second substrate 30. However, the second substrate 30 does not necessarily have a component arranged thereon.

### (4) Rectifier Circuit

In the above-described embodiment, the secondary-side circuit 4 includes a synchronous rectifier circuit using the first and second transistors Q1 and Q2. However, the secondary-side circuit 4 is only required to be able to rectify output voltage induced in the secondary-side winding 2c-2d, and may include a rectifier circuit instead of a synchronous rectifier circuit. The rectifier circuit includes, for example, a diode (one example of the rectifying element) in place of the first and second transistors Q1 and Q2 as a rectifying element. The diode has an anode (one example of a first element terminal) and a cathode (one example of a second element terminal), where current flows from the anode to the cathode in a forward direction, whereas current does not flow in a reverse direction from the cathode to the anode. Thus, the diode performs switching operation based on the difference in voltage applied to the anode and the cathode. The output voltage rectified with this rectifying action of the diode is obtained as an output from the rectifier circuit.

### 2. Another Embodiment

The structure of a rectifying-element-module sealing unit 200 according to another embodiment of the present invention is described below refer to the drawings.

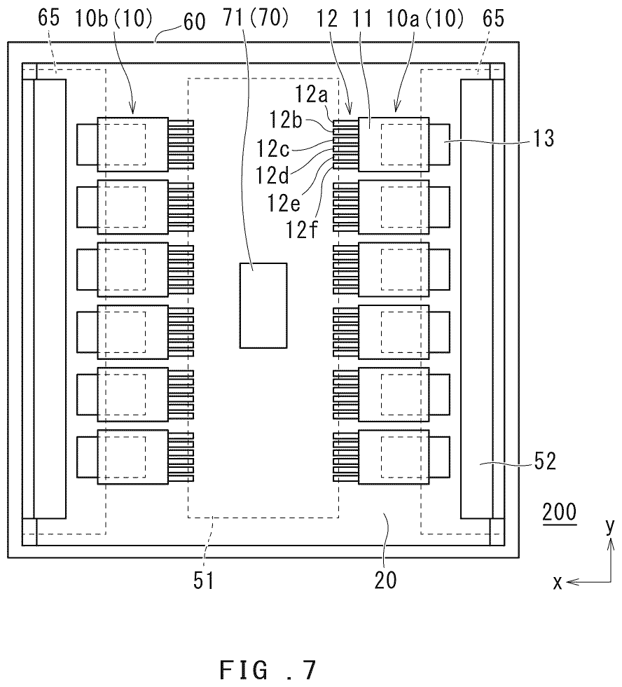

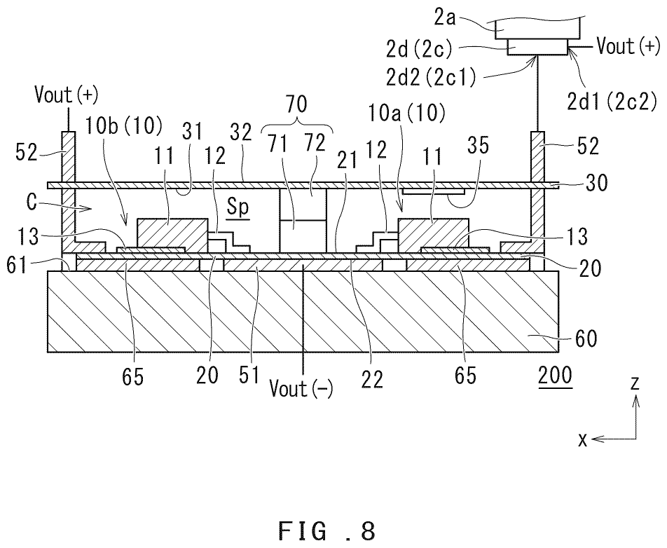

FIG. 7 is an upper view of the rectifier-circuit sealing unit 200 according to another embodiment of the present invention with an upper second substrate removed therefrom. FIG. 8 is a sectional view of the rectifier-circuit sealing unit 200 according to the other embodiment of the present invention along a III-III line of FIG. 1. However, components identical or corresponding to those of the rectifying-element-module sealing unit 100 of FIG. 1 as one embodiment of the present invention are provided with the same reference characters, and these and their relations common to those of the above-described embodiment are not described in detail unless otherwise specified.

The rectifier-circuit sealing unit 200 has the structure of the rectifying-element-module sealing unit 100 of FIG. 1 with the side wall portion 40 omitted therefrom. Note that the second substrate 30 is supported from below by the second wiring board 52, and a state of keeping a predetermined space with respect to the first substrate 20 is thereby maintained. With this, an area C open sideways between the first substrate 20 and the second substrate 30 is kept in a state of communicating with the outside.

When the rectifier-circuit sealing unit 200 as described above is not used in an environment with a high degree of contamination such as a site (factory) for metal plating, cooling the rectifying element modules 10 is performed by drawing air in the environment with a low degree of contamination, and thus adverse effects such as malfunction tend not to occur in the rectifier circuit.

The rectifier-circuit sealing unit 200 includes the cooling part 60 having a structure and effects similar to those of the rectifying-element-module sealing unit 100 of FIG. 1. That is, the cooling part 60 has the arrangement surface 61, which is an upper surface of the cooling part 60 and is also a horizontal plane. On the cooling part 60, the first wiring board 51 and the insulating heat dissipation sheets 65 are arranged on the arrangement surface 61.

With this, the rectifying element modules 10a of the first group and the rectifying element modules 10b of the second group can be insulated from one another, and heat of the first substrate 20 and the rectifying element modules 10 can be dissipated. Note that the insulating heat dissipation sheets 65 may be arranged so as to correspond to either of the rectifying element modules 10a of the first group and the rectifying element modules 10b of the second group.

Also with the above-described structure, as with the rectifier-circuit sealing unit 100 depicted in FIG. 6, in the cooling part 60, part of the first current path 90 of current flowing through the rectifying element module 10 is configured of the first penetrating current path 91. Thus, compared with a case in which the entire first current path 90 is formed as a wire on the first substrate 20, it is possible to suppress heat of the first substrate 20 generated by which the current flowing through the rectifying element module 10 flows through the first substrate 20. That is, by reducing the wire length where current flows in the first substrate 20, it is possible to suppress heat of the first substrate 20 due to current flowing through that wire. Thus, it is possible to suppress heat generation of the rectifying element module 10 due to the influence of heat of the first substrate 20. Furthermore, heat of the first substrate 20 and the rectifying element modules 10 is cooled by the cooling part 60. These can also suppress destruction and so forth of the rectifying element modules 10 due to heat.

Note that the cooling part 60 is only required to be able to cool the first substrate 20 and the rectifying element modules 10, and the structure of the cooling part 60 is not limited. Examples of the cooling part 60 include a water-cooled heat sink configured of one or more fins and conduits and so forth and capable of letting liquid such as water pass therethrough, an air-cooled heat sink configured of one or more fins and capable of dissipating heat, and so forth.

More specifically, the cooling part 60 is preferably configured of an electrically-conductive and thermally-conductive material, like a metal such as Cu or Al. With this, for example even when the rectifying element modules 10 handle a high current equal to or larger than 500 A in the rectifier circuit, favorable conductivity and heat dissipation can be achieved.

1. A rectifying-element-module sealing unit, comprising:
a rectifying element module having a rectifying element;
a first substrate in a plate shape having a first front surface and a first back surface and having the rectifying element module arranged on the first front surface;
a second substrate in a plate shape having a second front surface and a second back surface and arranged with respect to the first substrate so that the second front surface is opposed to the first front surface; and
a side wall portion forming, together with the first substrate and the second substrate, a sealed space having the rectifying element module arranged therein by covering areas open sideways between the first substrate and the second substrate.

2. The rectifying-element-module sealing unit according to claim 1, wherein
the rectifying element module is electrically connected to the first substrate, and
a component having performance that tends to be degraded by an influence of heat of the rectifying element module is arranged on the second front surface of the second substrate.

3. The rectifying-element-module sealing unit according to claim 1, wherein
the rectifying element module is included in a secondary-side circuit connected to a transformer.

4. The rectifying-element-module sealing unit according to claim 1, further comprising a cooling part arranged below the first back surface of the first substrate to cool the first substrate.

5. The rectifying-element-module sealing unit according to claim 4, wherein
the cooling part is formed of a conductive member,
part of a current path of current flowing through the rectifying element module is configured of a penetrating current path penetrating through the first substrate from the first front surface to the first back surface.

6. The rectifying-element-module sealing unit according to claim 1, further comprising a connector supporting the second substrate with respect to the first substrate and electrically connecting the first substrate and the second substrate together.

7. The rectifying-element-module sealing unit according to claim 1, wherein
the side wall portion is formed of an insulating member.

8. A rectifying-element-module sealing unit, comprising:
a rectifying element module having a rectifying element;
a first substrate in a plate shape having a first front surface and a first back surface and having the rectifying element module arranged on the first front surface;
a second substrate in a plate shape having a second front surface and a second back surface and arranged with respect to the first substrate so that the second front surface is opposed to the first front surface; and
a cooling part arranged below the first back surface of the first substrate to cool the first substrate, wherein
the cooling part is formed of a conductive member, and
part of a current path of current flowing through the rectifying element module is configured of a penetrating current path penetrating through the first substrate from the first front surface to the first back surface.

9. The rectifying-element-module sealing unit according to claim 2, wherein
the rectifying element module is included in a secondary-side circuit connected to a transformer.

10. The rectifying-element-module sealing unit according to claim 2, further comprising a cooling part arranged below the first back surface of the first substrate to cool the first substrate.

11. The rectifying-element-module sealing unit according to claim 2, further comprising a connector supporting the second substrate with respect to the first substrate and electrically connecting the first substrate and the second substrate together.

12. The rectifying-element-module sealing unit according to claim 2, wherein
the side wall portion is formed of an insulating member.
